(19) United States
(12) Patent Application Publication
(10) Pub. No.: US 2001/0005622 A1
(43) Pub. Date: Jun. 28, 2001

(54) Method for manufacturing gate electrode with vertical side profile

(76) Inventors: Jun-Dong Kim, Ichon-shi (KR); Young-Hun Bae, Ichon-shi (KR); Tae-Woo Jung, Ichon-shi (KR); Dong-Duk Lee, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/736,132

(22) Filed: Dec. 15, 2000

(30) Foreign Application Priority Data
Dec. 22, 1999 (KR) 1999-60678

(51) Int. Cl. H01L 21/4763; H01L 21/3205

(52) U.S. Cl. 438/592; 438/720

(57) ABSTRACT

A method for manufacturing a gate electrode, the method including the steps of forming upon a semiconductor substrate a polysilicon layer, a metal nitride layer, a tungsten layer and a photoresist layer, patterning the photoresist layer on the tungsten layer into a predetermined configuration, etching the tungsten layer, the metal nitride layer, a portion of the polysilicon layer into the predetermined configuration by using a mixed etchant of fluorine and chlorine species etchant, and patterning the remaining polysilicon layer into the predetermined configuration by using chlorine etchant.

### FIELD OF THE INVENTION

The present invention relates to a method for manufacturing a gate electrode; and, more particularly, to a method for manufacturing the gate electrode with a vertical side profile and an etch uniformity by applying a first over etch step using a mixed etchant of fluorine and chlorine etchant.

### DESCRIPTION OF THE PRIOR ART

As is well known, a dynamic random access memory (DRAM) with a memory cell comprised of a transistor and a capacitor has a higher degree of integration mainly due to downsizing through micronization. However, there is still a demand for downsizing the area of the memory cell, under increased transistor and circuit speeds and improved reliability. Such demands for increased density, performance and reliability require formation of device features with high precision and uniformity.

Furthermore, as integration increases and device feature size decreases, linewidths of a word line and a bit line are reduced so that gate resistance increases. To overcome this problem, it is necessary to increase a gate height or employ a low resistance material as a gate electrode. However, if the gate height increases, the step height and aspect ratio are higher so that it is difficult to obtain a good step coverage. Hence, the usual solution is to employ a low resistance gate electrode.

Therefore, a memory cell having low resistance gate electrodes as been researched and developed such as titanium silicide (TiSi₂), cobalt silicide (CoSi₂), tungsten (W) or the like instead of high resistance materials such as polysilicon and the other silicide materials, as illustrated in Table 1.

TABLE 1

| | TiSi₂ | CoSi₂ | MoSi₂ | WSi₂ | ZrSi₂ | W |
|---|---|---|---|---|---|---|
| Rs (μΩ · cm) | 13˜25 | 18˜25 | ˜100 | ˜70 | 33˜42 | 10˜13 |

W metal is particularly appropriate among these low resistance materials for gate electrodes due to its especially low resistance property in which gate electrode structure comprises a W layer, a tungsten nitride (WN) or titanium nitride (TiN) barrier layer, and a polysilicon layer. However, in W-WN-polysilicon structure, there is a problem when adopting a conventional etching process. That is, when using more than a predetermined amount of fluorine species etchant, such as hydrogen fluoride (HF), for patterning the W and WN layer, underlying layers, e.g., polysilicon and gate oxide layers are attacked by the fluorine species etchant so that the underlying layers may be eroded. Thus, it is impossible to obtain the gate electrode structure with a vertical side profile. On the other hand, in the case of using less than the predetermined amount of etchant, residues of W and WN layers remaining upon the polysilicon layer interfere with the normal etching process, because these residues serve as etching barriers.

As a result of these factors, the gate electrode structure is formed abnormally, thereby inducing transistor performance degradation eventually.

### SUMMARY OF THE INVENTION

It is, therefore, an object of the present invention to provide a method for manufacturing a tungsten gate electrode with an enhanced vertical side profile by applying a first over etch step using a mixed etchant of a fluorine species etchant and a chlorine species etchant.

In accordance with one aspect of the present invention, there is provided a method for manufacturing a gate electrode, the method comprising the steps of: a) forming in this order upon a semiconductor substrate a polysilicon layer, a metal nitride layer, a tungsten layer and a photoresist layer; b) patterning the photoresist layer on the tungsten layer into a predetermined configuration; c) etching the tungsten layer, the metal nitride layer, and a portion of the polysilicon layers into the predetermined configuration by using a mixed etchant of fluorine and chlorine species etchant; and d) patterning the remaining polysilicon layer into the predetermined configuration by using chlorine etchant.

### BRIEF DESCRIPTION OF THE DRAWING

The above and other objects and features of the present invention will become apparent from the following description of the preferred embodiment given in conjunction with the accompanying drawings, in which:

FIGS. 1 to 4 are cross sectional views setting forth a method for manufacturing a W/WN/polysilicon gate electrode in accordance with a preferred embodiment of the present invention.

### DETAILED DESCRIPTION OF THE PREFERRED EMBODIMENTS

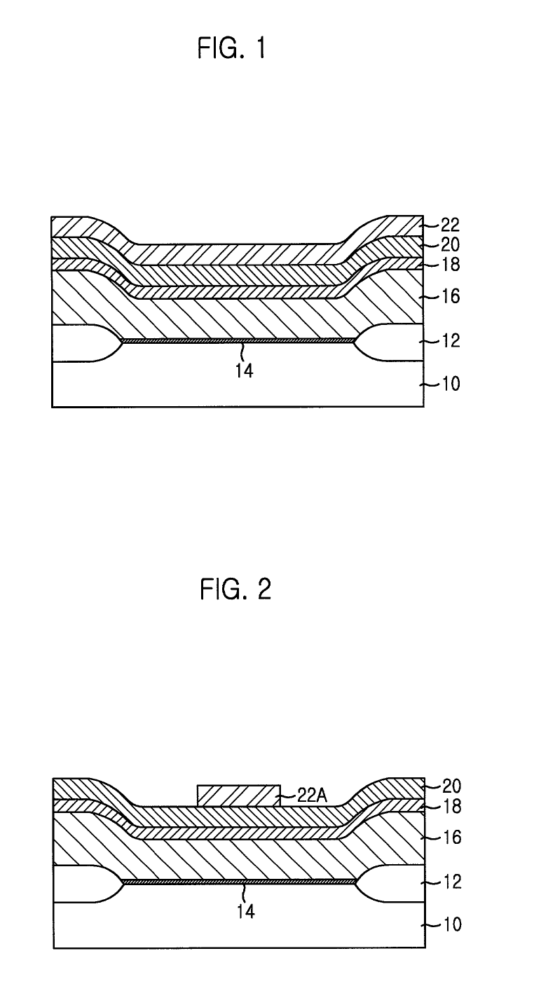

There are provided in FIGS. 1 to 4 cross sectional views setting forth a method for manufacturing a tungsten gate electrode having a vertical side profile in accordance with a preferred embodiment of the present invention. It should be noted that like parts appearing in FIGS. 1 to 4 are represented by like reference numerals.

Referring to FIG. 1, there is provided a cross sectional view setting forth a first step of forming a first polysilicon layer 16, then a tungsten nitride layer 18, then a tungsten layer 20, and finally a photoresist layer 22 on a semiconductor substrate 10. Here, the tungsten nitride layer 18 is a barrier layer so that it can be substituted by another metal nitride layer such as a titanium nitride (TiN) layer or the like. Reference numerals 12, 14 denote isolation regions and gate oxide layer, respectively. The tungsten and the tungsten nitride layers 20, 18 are formed by using a method such as a chemical vapor deposition (CVD) or a physical vapor deposition (PVD). An annealing process may be carried out after depositing the tungsten and tungsten nitride layers 20, 18 to densify the tungsten layer 20.

In a next step, the photoresist layer 22 is patterned into a predetermined configuration by using O₂ plasma, thereby obtaining the patterned photoresist layer 22A as shown in FIG. 2. The patterned photoresist layer 22A plays a role as a mask when subsequent etching steps are performed.

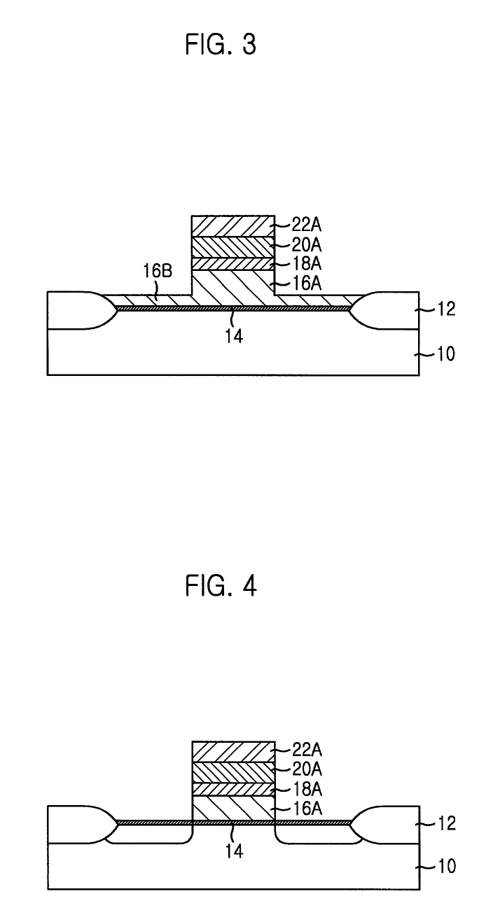

In an ensuing step, a first etch, i.e., over etch, is carried out as shown in FIG. 3. In the first etch step, the tungsten layer 20, the tungsten nitride layer 18 and a portion of the polysilicon layer 16 are patterned into the predetermined configuration by using a mixed etchant of fluorine and chlorine species etchant to prevent underlying layers from being attacked by fluorine species etchant. The result is a patterned tungsten layer 20A and a patterned tungsten nitride layer 18A. In more detail, the first etch step of the present invention is carried out to protect underlying layers, i.e., the polysilicon layer 16 and the gate oxide layer 14, from fluorine etchant's attack on condition that used gases are a mixture of nitrogen trifluoride gas (NF₃), chlorine gas (Cl₂) and inert gas of argon (Ar). In addition, a power ratio between source and bias powers of an inductively coupled plasma (ICP) ranges preferably from 1:1 to 3:1, and gas flow ratio between NF₃ and Cl₂ ranges from 0.5:1 to 3:1. It is preferable that the source and the bias powers are below 500 W and 300 W, respectively, and the concentration of NF₃ is below 100 standard cubic centimeters per minute (sccm), with a preferred range of from 25 to 75 sccm. Moreover, the chamber pressure is approximately 3˜20 mTorr and the temperature of an electrode is approximately 10˜60° C.

It is noted that the first etch process should be carried out until a portion of the polysilicon layer 16 is removed. That is, the polysilicon layer 16 is etched to a portion thereof, thereby obtaining an etched portion 16A and a remaining portion 16B as shown in FIG. 3. By doing this, the residue on the polysilicon layer 16 can be cleared away effectively so that etching barriers no longer exist. Furthermore, only a portion of the polysilicon layer 16 is removed in this etch step in order to prevent damage to the gate oxide layer 14 by the fluorine etchant, e.g., NF₃.

However, the first etch step may be carried out by separating into two steps according to the work condition. Namely, one step of the first etch step is performed until the tungsten and tungsten nitride layers 20, 18 are etched to be removed, and the other step of the first etch step is performed until a portion of the polysilicon layer 16 is removed.

After the first over etch step, a second etch is carried out for removing the remaining polysilicon layer 16B completely, as shown in FIG. 4. The second etch step is performed on condition that O₂ and HBr are added into Cl₂, wherein the concentration of Cl₂ is below 20 sccm and the ratio between O₂ and HBr is 1:8. It is preferable that the chamber pressure be kept below 100 mTorr. In this step, it is noted that fluorine species etchant is not used for etching the remaining polysilicon layer 16B because the gate oxide layer 14 may be attacked by fluorine species etchant.

The first and the second etch steps can be performed in an ICP chamber, where the temperature of the electrode is 10˜60° C. and the pressure is below 100 mTorr.

In the embodiment of the present invention, the hard mask is not used during the etch process but it can be employed between the tungsten layer 20 and the photoresist layer 22 providing that the hard mask will be needed in a post manufacturing step. Although the hard mask is used in the gate structure, the etching steps are the same as the case without the hard mask as aforementioned.

In comparison with the conventional etch process, the present invention provides the W/WN/polysilicon gate electrode with a vertical side profile by applying the first over etch step using mixed etchant of fluorine and chlorine etchant so that it is possible to enhance the transistor performance and reliability. In addition, the present invention utilizes ICP as an etch apparatus, whereby manufacturing cost can be reduced and productivity can be enhanced.

While the present invention has been described with respect to the particular embodiments, it will be apparent to those skilled in the art that various changes and modifications may be made without departing from the scope of the invention as defined in the following claims.

What is claimed is:

1. A method for manufacturing a gate electrode, the method comprising the steps of:
a) forming upon a semiconductor substrate a polysilicon layer, a metal nitride layer, a tungsten layer and a photoresist layer;
b) patterning the photoresist layer on the tungsten layer into a predetermined configuration;
c) etching the tungsten layer, the metal nitride layer, and a portion of the polysilicon layer into the predetermined configuration by using a mixed etchant of a fluorine species etchant and a chlorine species etchant; and
d) patterning the remaining polysilicon layer into the predetermined configuration by using chlorine etchant.

2. The method of claim 1, wherein the metal nitride layer is made of a material selected from a group consisting of a tungsten nitride and a titanium nitride.

3. The method of claim 1, wherein the steps c) and d) are carried out by an inductively coupled plasma (ICP).

4. The method of claim 1, wherein the fluorine species etchant is nitrogen trifluoride (NF₃) and the chlorine species etchant is chlorine (Cl₂).

5. The method of claim 3, wherein the mixed etchant used in the step c) includes NF₃, Cl₂ and argon (Ar).

6. The method of claim 4, wherein a concentration ratio between NF₃ and Cl₂ ranges from 0.5:1 to 3:1.

7. The method of claim 5, wherein the step c) is carried out on conditions that the concentrations of NF₃ and Cl₂ are less than 100 sccm respectively, a ratio between a source power and a bias power ranges from 1:1 to 3:1, and a chamber pressure is below 100 mTorr.

8. The method of claim 7, wherein the source power is below 500 W and the bias power is below 300 W.

9. The method of claim 7, wherein the concentration of NF₃ is 25˜75 sccm.

10. The method of claim 3, wherein the step d) is carried out on conditions that a concentration of Cl₂ is less than 20 sccm, a ratio between O₂ and HBr is at least 1:8, and a chamber pressure is below 100 mTorr.

11. The method of claim 1, wherein the steps c) and d) are carried out on condition that a temperature of an electrode ranges from 10˜60° C.

12. The method of claim 1, wherein the step a) includes a step of forming a hard mask between the tungsten layer and the photoresist layer.
